(19) United States
(12) Patent Application Publication
(10) Pub. No.: US 2025/0048672 A1
(43) Pub. Date: Feb. 6, 2025

(54) SEMICONDUCTOR DEVICE

(71) Applicant: ROHM CO., LTD., Kyoto (JP)

(72) Inventors: Shoji TAKEI, Kyoto (JP); Yuji MATSUMOTO, Kyoto (JP)

(73) Assignee: ROHM CO., LTD., Kyoto (JP)

(21) Appl. No.: 18/789,460

(22) Filed: Jul. 30, 2024

(30) Foreign Application Priority Data
Aug. 3, 2023 (JP) 2023-127274

(51) Int. Cl. H01L 29/78; H01L 29/417; H01L 29/423; H01L 29/66

(52) U.S. Cl. CPC H01L 29/7816; H01L 29/41766; H01L 29/42376; H01L 29/66696

(57) ABSTRACT

A semiconductor device includes: a semiconductor chip having a first main surface and a second main surface opposite to the first main surface; a first drain region of first conductivity type formed in a surface layer portion of the first main surface; a back gate region of second conductivity type spaced apart from the first drain region in the surface layer portion of the first main surface; a source region of the first conductivity type spaced inward from a peripheral edge of the back gate region in a surface layer portion of the back gate region; a back gate contact region of the second conductivity type electrically isolated from the source region in the surface layer portion of the back gate region; and a gate electrode facing a channel region formed in the back gate region between the peripheral edge of the back gate region and the source region.

### CROSS-REFERENCE TO RELATED APPLICATION

This application is based upon and claims the benefit of priority from Japanese Patent Application No. 2023-127274, filed on Aug. 3, 2023, the entire contents of which are incorporated herein by reference.

### TECHNICAL FIELD

The present disclosure relates to a semiconductor device.

### BACKGROUND

In the related art, there is disclosed a semiconductor device including a p-type silicon substrate and an n-channel type LDMOS formed on the silicon substrate.

### SUMMARY

An embodiment of the present disclosure provides a semiconductor device which is capable of switching a connection destination of a back gate contact region between a source region and a drain region.

According to an embodiment of the present disclosure, there is provided a semiconductor device, which includes: a semiconductor chip having a first main surface and a second main surface opposite to the first main surface; a first drain region of a first conductivity type formed in a surface layer of the first main surface; a back gate region of a second conductivity type formed to be spaced apart from the first drain region in the surface layer of the first main surface; a source region of the first conductivity type formed to be spaced inward from a peripheral edge of the back gate region in a surface layer of the back gate region; a back gate contact region of the second conductivity type formed to be electrically isolated from the source region in the surface layer of the back gate region; and a gate electrode facing a channel region formed in the back gate region between the peripheral edge of the back gate region and the source region.

### BRIEF DESCRIPTION OF DRAWINGS

The accompanying drawings, which are incorporated in and constitute a part of the specification, illustrate embodiments of the present disclosure.

FIG. 1 is a schematic plan view of a semiconductor device according to an embodiment of the present disclosure.

FIG. 2 is a view showing an example of a planar layout of impurity diffusion regions in an LDMOS region.

FIG. 3 is a view showing an example of a planar shape of a field insulating film in the LDMOS region.

FIG. 4 is an enlarged view of a portion surrounded by dashed line IV in FIG. 3.

FIG. 5 is a view showing an example of a planar shape of a gate electrode in the LDMOS region.

FIG. 6 is a cross-sectional view taken along line VI-VI shown in FIG. 5.

FIG. 7 is an enlarged view of a portion surrounded by dashed line VII in FIG. 6.

FIG. 8 is a circuit diagram of the semiconductor device.

FIG. 9 is a graph showing a relationship between a fourth width of a back gate contact region in a second direction and an on-breakdown voltage of the semiconductor device.

FIG. 10A is a view showing a part of a manufacturing process of the semiconductor device, which corresponds to FIG. 7.

FIG. 10B is a view showing a next step of FIG. 10A.

FIG. 10C is a view showing a next step of FIG. 10B.

FIG. 10D is a view showing a next step of FIG. 10C.

FIG. 10E is a view showing a next step of FIG. 10D.

FIG. 10F is a view showing a next step of FIG. 10E.

FIG. 10G is a view showing a next step of FIG. 10F.

FIG. 10H is a view showing a next step of FIG. 10G.

FIG. 10I is a view showing a next step of FIG. 10H.

FIG. 10J is a view showing a next step of FIG. 10I.

FIG. 10K is a view showing a next step of FIG. 10J.

FIG. 10L is a view showing a next step of FIG. 10K.

FIG. 10M is a view showing a next step from FIG. 10L.

FIG. 10N is a view showing a next step of FIG. 10M.

FIG. 11 is a view showing a first modification of a planar structure of the semiconductor device, which corresponds to a portion surrounded by dashed line XI in FIG. 4.

FIG. 12 is a view showing a second modification of a planar structure of the semiconductor device, which corresponds to FIG. 11.

FIG. 13 is a schematic cross-sectional view of a semiconductor device according to another embodiment of the present disclosure, which corresponds to FIG. 7.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings.

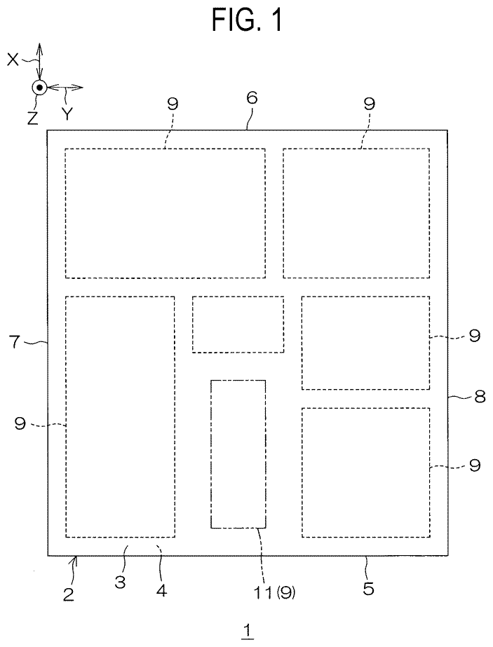

FIG. 1 is a schematic plan view of a semiconductor device 1 according to an embodiment of the present disclosure.

The semiconductor device 1 includes a semiconductor chip 2 formed in a rectangular parallelepiped shape. The semiconductor chip 2 forms an outer shape of the semiconductor device 1 and has, for example, a structure in which a single crystal semiconductor material is formed in a chip shape (rectangular parallelepiped shape). The semiconductor chip 2 is made of a semiconductor material such as Si or SiC. The semiconductor chip 2 has a first main surface 3 on one side, a second main surface 4 on the other side, and first to fourth side surfaces 5 to 8 connecting the first main surface 3 and the second main surface 4. The first to fourth side surfaces 5 to 8 include a first side surface 5, a second side surface 6, a third side surface 7, and a fourth side surface 8. The third side surface 7 and the fourth side surface 8 extend in a first direction X and face each other in a second direction Y which is orthogonal to the first direction X. The first side surface 5 and the second side surface 6 extend in the second direction Y and face each other in the first direction X.

The first main surface 3 and the second main surface 4 are formed in a square shape in a plan view when viewed from a third direction Z (a normal direction of the first main surface 3 and the second main surface 4) (hereinafter, simply referred to as “plan view”). The first main surface 3 may also be referred to as a device surface on which functional devices are formed. The second main surface 4 may also be referred to as a non-device surface on which no functional device is formed. A plurality of device regions 9 are formed on the first main surface 3. The number and an arrangement of device regions 9 are arbitrary. The plurality of device regions 9 may include functional devices formed by using a surface layer portion of the first main surface 3. The functional devices may include, for example, at least one selected from the group of a semiconductor switching device, a semiconductor rectifying device, and a passive device. The functional devices may include, for example, a circuit network obtained by combining at least two selected from the group of a semiconductor switching device, a semiconductor rectifying device, and a passive device.

The semiconductor switching device may include, for example, at least one selected from the group of a metal oxide semiconductor field effect transistor (MOSFET), a bipolar junction transistor (BJT), an insulated gate bipolar junction transistor (IGBT), and a junction field effect transistor (JFET). The semiconductor rectifying device may include, for example, at least one selected from the group of a pn junction diode, a pin junction diode, a Zener diode, a Schottky barrier diode, and a fast recovery diode. The passive device may include, for example, at least one selected from the group of a resistor, a capacitor, and an inductor.

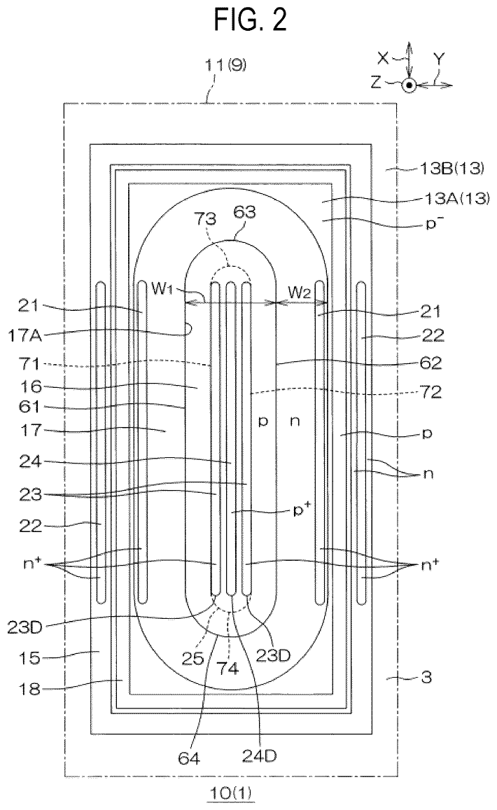

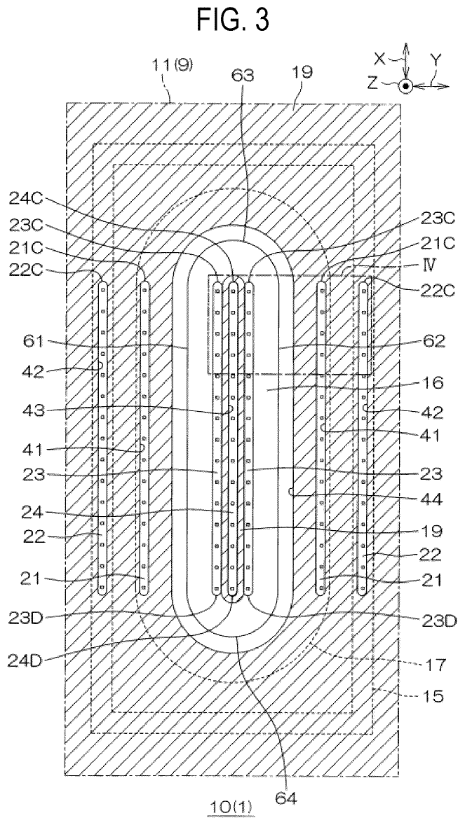

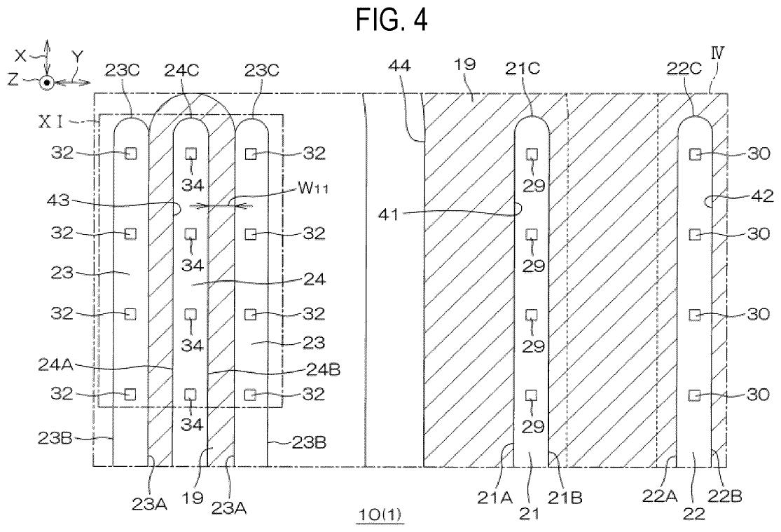

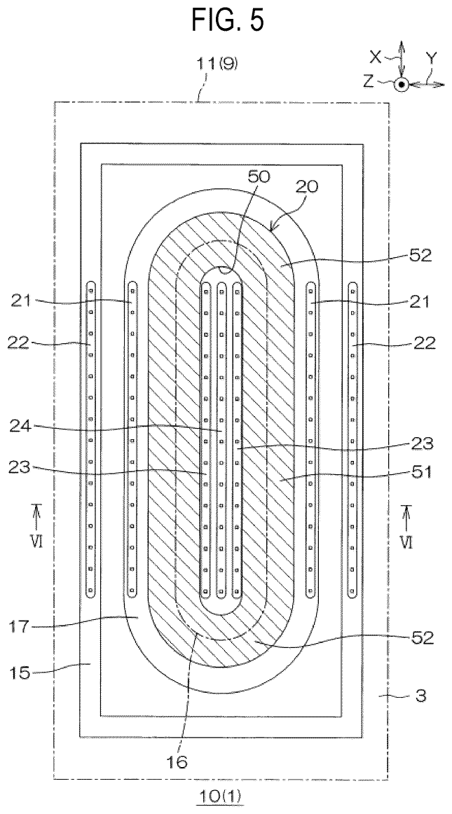

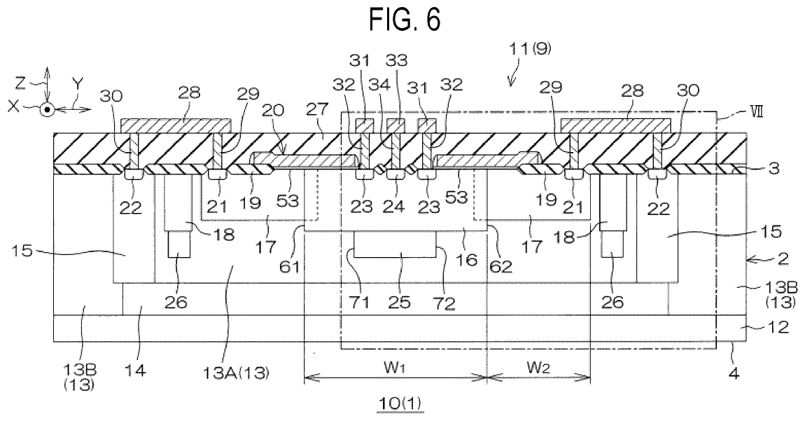

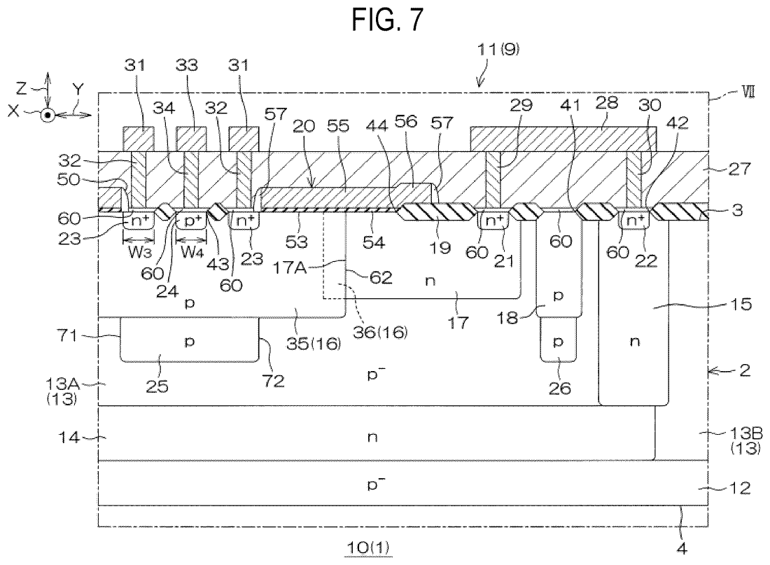

FIG. 2 is a view showing an example of a planar layout of impurity diffusion regions in an LDMOS region 11. FIG. 3 is a view showing an example of a planar shape of a field insulating film 19 in the LDMOS region 11. FIG. 4 is an enlarged view of a portion surrounded by dashed line IV in FIG. 3. FIG. 5 is a view showing an example of a planar shape of a gate electrode 20 in the LDMOS region 11. FIG. 6 is a cross-sectional view taken along line VI-VI shown in FIG. 5. FIG. 7 is an enlarged view of a portion surrounded by dashed line VII in FIG. 6. A structure of the LDMOS region 11 in which a lateral double diffused MOSFET (LDMOSFET) 10 as an example of a functional device is formed in the plurality of device regions 9 will be specifically described with reference to FIGS. 1 to 7.

The LDMOSFET 10 includes a first p-type region 12, a second p-type region 13, a buried region 14, a first well region (well region) 15, a back gate region 16, a drift region 17, a second well region 18, a field insulating film 19, a gate electrode 20, a first drain region 21, a second drain region 22, a source region 23, a back gate contact region 24, a first impurity region 25, a second impurity region 26, an interlayer insulating film 27, a drain wiring 28, a first drain contact 29, a second drain contact 30, a source wiring 31, a source contact 32, a back gate wiring 33, and a back gate contact 34.

Referring to FIGS. 6 and 7, the first p-type region 12 is formed in a surface layer portion of the second main surface 4 of the semiconductor chip 2. The first p-type region 12 is a p-type (second conductivity type) impurity region. The first p-type region 12 is formed over the entire surface layer portion of the second main surface 4 and is exposed from the second main surface 4 and the first to fourth side surfaces 5 to 8 (see FIG. 1).

A p-type impurity concentration of the first p-type region 12 may be 1.0×10¹³ cm⁻³ or more and 1.0×10¹⁵ cm⁻³ or less. A thickness of the first p-type region 12 may be 100 μm or more and 500 μm or less. The first p-type region 12 may have a structure in which a p-type epitaxial layer (Si epitaxial layer) is laminated over a p-type semiconductor substrate formed on the side of the second main surface 4. The first p-type region 12 may be a p-type semiconductor substrate. Since the first p-type region 12 has a relatively low impurity concentration, it may be referred to as a p⁻-type region.

Referring to FIGS. 6 and 7, the second p-type region 13 is formed in the surface layer portion of the first main surface 3 of the semiconductor chip 2. The second p-type region 13 is a p-type impurity region. The second p-type region 13 is formed over the entire surface layer portion of the first main surface 3 and is exposed from the first main surface 3 and the first to fourth side surfaces 5 to 8 (see FIG. 1). A thickness of the second p-type region 13 is smaller than the thickness of the first p-type region 12, for example. The thickness of the second p-type region 13 may be 5 μm or more and 20 μm or less. In the present embodiment, the second p-type region 13 may be a p-type epitaxial layer. The p-type impurity concentration of the second p-type region 13 may be the same as the p-type impurity concentration of the first p-type region 12. The p-type impurity concentration of the second p-type region 13 may be 1.0×10¹³ cm⁻³ or more and 1.0×10¹⁵ cm⁻³ or less. Since the second p-type region 13 has a relatively low impurity concentration, it may also be referred to as a p⁻-type region.

The second p-type region 13 is insulated and separated into a plurality of regions by an element isolation structure (for example, an element isolation well, a deep trench isolation (DTI), a shallow trench isolation (STI), etc.), which is not shown. The element isolation structure partitions the semiconductor chip 2 into a plurality of device regions 9. FIGS. 2 to 7 show the second p-type region 13 forming the LDMOS region 11 among the plurality of separated second p-type regions 13.

Referring to FIG. 2, the second p-type region 13 includes a p-type inner region 13A and an annular p-type outer region 13B that surrounds sides of the p-type inner region 13A and contacts the element isolation structure. The back gate region 16, the drift region 17, and the like are formed in the p-type inner region 13A.

Referring to FIGS. 6 and 7, the buried region 14 is an n-type (first conductivity type) region (B/L layer) buried between the first p-type region 12 and the p-type inner region 13A. Specifically, the buried region 14 extends in a layered manner along the first main surface 3 so as to straddle a boundary between the first p-type region 12 and the p-type inner region 13A (that is, the second p-type region 13). Although not shown, the buried region 14 has a square shape in a plan view. The buried region 14 is electrically connected to the first p-type region 12 and the second p-type region 13. A thickness of the buried region 14 may be 0.1 μm or more and 5 μm or less. The n-type impurity concentration of the buried region 14 may be 1.0×10¹⁶ cm⁻³ or more and 1.0×10²¹ cm⁻³ or less. The n-type impurity concentration of the buried region 14 may be higher than the n-type impurity concentration of the drift region 17. The n-type impurity concentration of the buried region 14 may be the same as the n-type impurity concentration of the drift region 17.

Referring to FIGS. 2, 6, and 7, the first well region 15 is an n-type impurity region formed in a surface layer portion of the second p-type region 13. The first well region 15 is formed in an annular shape in a plan view. Referring to FIG. 2, the first well region 15 may be formed in a square annular shape that extends long in the first direction X in a plan view. The first well region 15 overlaps a peripheral edge of the buried region 14 in a plan view. A bottom of the first well region 15 reaches the buried region 14. A depth of the first well region 15 is the same over the entire circumferential region. The peripheral edge of the buried region 14 contacts the entire circumferential region of the first well region 15 from below.

The n-type impurity concentration of the first well region 15 may be 1.0×10¹⁶ cm⁻³ or more and 1.0×10²⁰ cm⁻³ or less. The n-type impurity concentration of the first well region 15 may be higher than the n-type impurity concentration of the drift region 17. The n-type impurity concentration of the first well region 15 may be the same as the n-type impurity concentration of the drift region 17.

Referring to FIGS. 2, 6, and 7, the annular first well region 15 surrounds the sides of the p-type inner region 13A in the second p-type region 13. Since the bottom of the first well region 15 reaches the buried region 14, the p-type inner region 13A is surrounded by an n-type region including the buried region 14 and the first well region 15 in the first direction X, the second direction Y, and the third direction Z. As a result, the p-type inner region 13A is electrically isolated from the p-type outer region 13B and the first p-type region 12 by the n-type region including the buried region 14 and the first well region 15.

Referring to FIGS. 6 and 7, the back gate region 16 is a region in the LDMOS region 11 to which the back gate voltage of the LDMOSFET 10 is applied. The back gate region 16 is a p-type back gate region and is formed in a surface layer portion of the p-type inner region 13A. A depth of a bottom of the back gate region 16 is smaller than that of the bottom of the first well region 15. The depth of the bottom of the back gate region 16 is smaller than that of a bottom of the drift region 17.

Referring to FIGS. 2, 3, and 6, the back gate region 16 is formed in an elliptical shape that extends long in the first direction X in a plan view. The back gate region 16 has a first peripheral edge 61 and a second peripheral edge 62 that extend linearly along the first direction X while being spaced apart from each other. The back gate region 16 has a third peripheral edge 63 and a fourth peripheral edge 64 that connect the first peripheral edge 61 and the second peripheral edge 62. The third peripheral edge 63 and the fourth peripheral edge 64 face each other in the first direction X. The third peripheral edge 63 and the fourth peripheral edge 64 are formed in an arc shape that swells outward in the first direction X.

Referring to FIGS. 6 and 7, the back gate region 16 includes a low concentration portion (second portion) 36 formed at a peripheral edge of the back gate region 16. The low concentration portion 36 is formed over the entire circumferential region of the back gate region 16. The low concentration portion 36 is formed at the peripheral edge of the back gate region 16 except for the vicinity of the bottom. The low concentration portion 36 is formed in an elliptical annular shape along the peripheral edge (the first peripheral edge 61 to the fourth peripheral edge 64) of the back gate region 16. An outer peripheral portion of the low concentration portion 36 is in contact with the drift region 17 over the entire circumferential region of the back gate region 16. The p-type impurity concentration of the back gate region 16 may be, for example, 1.0×10¹⁵ cm⁻³ or more and 5.0×10¹⁶ cm⁻³ or less. A depth of a bottom of the low concentration portion 36 is the same as that of the bottom of the drift region 17, which will be described below.

Referring to FIGS. 6 and 7, a portion of the back gate region 16 excluding the low concentration portion 36 is a high concentration portion (first portion) 35. A p-type impurity concentration of a high concentration portion 35 may be, for example, 1.0×10¹⁶ cm⁻³ or more and 5.0×10¹⁷ cm⁻³ or less.

Referring to FIGS. 6 and 7, the drift region 17 is formed in the surface layer portion of the p-type inner region 13A. The drift region 17 is an n-type drift region. The n-type impurity concentration of the drift region 17 may be, for example, 5.0×10¹⁵ cm⁻³ or more and 5.0×10¹⁷ cm⁻³ or less. The depth of the bottom of the drift region 17 is smaller than that of the bottom of the first well region 15. The depth of the bottom of the drift region 17 is larger than that of the bottom of the back gate region 16. A second width W₂ of the drift region 17 is smaller than a first width W₁ of the back gate region 16.

Referring to FIG. 2, the drift region 17 surrounds the back gate region 16 in a plan view. The drift region 17 may be formed in an elliptical annular shape that extends long in the first direction X in a plan view. An inner peripheral edge 17A of the drift region 17 is in contact with the peripheral edge (the first peripheral edge 61 to the fourth peripheral edge 64) of the back gate region 16 over the entire circumferential region.

Referring to FIGS. 6 and 7, the second well region 18 is a p-type impurity region formed in the surface layer portion of the second p-type region 13. The p-type impurity concentration of the second well region 18 may be, for example, 1.0×10¹⁶ cm⁻³ or more and 5.0×10¹⁷ cm⁻³ or less. The p-type impurity concentration of the second well region 18 is the same as the p-type impurity concentration of the high concentration portion 35 of the second well region 18. The p-type impurity concentration of the second well region 18 may be higher than the p-type impurity concentration of the high concentration portion 35. The p-type impurity concentration of the second well region 18 may be lower than the p-type impurity concentration of the high concentration portion 35.

Referring to FIG. 2, the second well region 18 may be formed in a square annular shape that extends long in the first direction X in a plan view. The second well region 18 surrounds the drift region 17 in a plan view. The second well region 18 is formed to be spaced apart from the drift region 17 in both the first direction X and the second direction Y when seen in a plan view. The second well region 18 is surrounded by the first well region 15 in a plan view. The second well region 18 is formed to be spaced apart from the first well region 15 in both the first direction X and the second direction Y in a plan view. Although not shown, the second well region 18 may be formed in an elliptical annular shape that extends long in the first direction X in a plan view.

Referring to FIGS. 2 and 3, the field insulating film 19 is formed over the first main surface 3 of the semiconductor chip 2. The field insulating film 19 covers the first main surface 3. For the sake of clarity, the field insulating film 19 is shown with hatching in FIG. 3. The non-hatched regions in FIG. 3 are regions that are not covered with the field insulating film 19. The field insulating film 19 may be, for example, a LOCOS oxide film formed by selectively oxidizing the surface (the first main surface 3) of the second p-type region 13.

Referring to FIG. 3, the field insulating film 19 has a first opening portion 41, a second opening portion 42, a third opening portion 43, and a fourth opening portion 44. The first opening portion 41 is formed in an elliptical shape that extends long in the first direction X in a plan view. The first opening portion 41 exposes a portion (the first drain region 21) of the drift region 17. The second opening portion 42 is formed in an elliptical shape that extends long in the first direction X in a plan view. The second opening portion 42 exposes a portion (the second drain region 22) of the first well region 15.

Referring to FIG. 3, the third opening portion 43 is formed in an elliptical shape. The third opening portion 43 exposes a portion (the back gate contact region 24) of the back gate region 16. The fourth opening portion 44 extends long in the first direction X in a plan view and is formed in an elliptical annular shape surrounding the third opening portion 43 in a plan view. The fourth opening portion 44 exposes the back gate region 16 and the drift region 17. An opening width of the elliptical annular fourth opening portion 44 is larger than an opening width of the elliptical third opening portion 43.

Referring to FIG. 3, the first opening portion 41 may be formed in pair so as to sandwich the third opening portion 43 and the fourth opening portion 44 in the second direction Y. The second opening portion 42 may be formed in pair so as to sandwich the first opening portion 41, the third opening portion 43, and the fourth opening portion 44 in the second direction Y. The first opening portion 41, the second opening portion 42, and the third opening portion 43 may be formed in a square shape that extends long in the first direction X in a plan view.

Referring to FIGS. 6 and 7, the first drain region 21 is formed in a surface layer portion of the drift region 17. The first drain region 21 may have a higher n-type impurity concentration than the drift region 17. The n-type impurity concentration of the first drain region 21 may be, for example, 1.0×10¹⁶ cm⁻³ or more and 5.0×10¹⁷ cm⁻³ or less.

Referring to FIG. 4, the first drain region 21 is exposed from the field insulating film 19 at the first opening portion 41. The first drain region 21 has a first side portion 21A and a second side portion 21B that extend along the first direction X while being spaced apart from each other. The first drain region 21 has a third side portion 21C and a fourth side portion 21D (see FIG. 3) that connect the first side portion 21A and the second side portion 21B. The third side portion 21C and the fourth side portion 21D are formed in an arc shape that swells outward in the first direction X. The first side portion 21A to the fourth side portion 21D may all be arranged inside an outer peripheral edge of the drift region 17 in a plan view.

Referring to FIGS. 6 and 7, the second drain region 22 is formed in a surface layer portion of the first well region 15. The second drain region 22 may have a higher n-type impurity concentration than the first well region 15. The n-type impurity concentration of the second drain region 22 may be, for example, 1.0×10¹⁶ cm⁻³ or more and 5.0×10¹⁷ cm⁻³ or less.

Referring to FIG. 4, the second drain region 22 is exposed from the field insulating film 19 at the second opening portion 42. The second drain region 22 has a first side portion 22A and a second side portion 22B that extend along the first direction X while being spaced apart from each other. The second drain region 22 has a third side portion 22C and a fourth side portion 22D (see FIG. 3) that connect the first side portion 22A and the second side portion 22B. The third side portion 22C and the fourth side portion 22D are formed in an arc shape that swells outward in the first direction X. The first side portion 22A to the fourth side portion 22D may all be arranged inside an outer peripheral edge of the first well region 15 in a plan view.

Referring to FIG. 5, the gate electrode 20 is formed over the first main surface 3 of the semiconductor chip 2. For the sake of clarity, the gate electrode 20 is shown with hatching in FIG. 5. The gate electrode 20 may include a conductive material such as polysilicon or aluminum, for example. The gate electrode 20 is formed in an annular shape in a plan view. The gate electrode 20 may include a pair of first portions 51 that face each other in the second direction Y, and second portions 52 that connect the pair of first portions 51 to each other. In the present embodiment, the first portions 51 are formed in a linear shape that extends in parallel to each other along the first direction X, and the second portions 52 are formed in an arc shape that swells outward in the first direction X. An opening portion 50 is formed in a central portion of the gate electrode 20 partitioned by the pair of first portions 51 and the pair of second portions 52. The opening portion 50 is formed in an elliptical shape extending along the first direction X in a plan view. The opening portion 50 exposes a portion of the back gate region 16. Specifically, the opening portion 50 integrally exposes the source region 23 and the back gate contact region 24.

Referring to FIG. 7, a region in the back gate region 16 which the gate electrode 20 faces is a channel region 53 of the LDMOSFET 10. Formation of a channel in the channel region 53 is controlled by the gate electrode 20. A thickness of the gate electrode 20 may be, for example, 0.1 μm or more and 0.4 μm or less. The gate electrode 20 provides a threshold voltage (V_{TH}) when forming the channel in the back gate region 16.

Referring to FIG. 7, a gate insulating film 54 is formed between the gate electrode 20 and the first main surface 3. The gate insulating film 54 may be, for example, a silicon oxide (SiO₂) film formed by thermally oxidizing the first main surface 3. A thickness of the gate insulating film 54 may be, for example, 0.2 nm or more and 100 nm or less.

Referring to FIG. 7, the gate electrode 20 may integrally include an annular control portion 55 on the side of the opening portion 50 (inside) and an annular field plate portion 56 outside the control portion 55. The control portion 55 of the gate electrode 20 covers the back gate region 16 (the channel region 53) and the drift region 17, via the gate insulating film 54, sequentially from the inside to the outside. The field plate portion 56 of the gate electrode 20 is formed over the field insulating film 19 over the drift region 17.

Referring to FIG. 7, a sidewall structure 57 is formed at a side portion of the gate electrode 20. The sidewall structure 57 is formed at both an inner side portion (a side portion of the opening portion 50) and an outer side portion of the gate electrode 20.

Referring to FIG. 7, a silicide layer 60 is formed over the first main surface 3 except for a portion where the gate insulating film 54 is formed. Therefore, the silicide layer 60 may be a compound containing silicon (Si) and a transition metal such as titanium (Ti), cobalt (Co), nickel (Ni), platinum (Pt), or tungsten (W).

Referring to FIG. 7, the source region 23 and the back gate contact region 24 are formed in a surface layer portion of the back gate region 16. The source region 23 has a band shape extending along the first direction X. The source region 23 is an n-type impurity region. The n-type impurity concentration of the source region 23 may be, for example, 1.0×10¹⁶ cm⁻³ or more and 5.0×10¹⁷ cm⁻³ or less. The source region 23 may have a higher n-type impurity concentration than the drift region 17. The source region 23 includes a pair of source regions 23 sandwiching the back gate contact region 24 in the second direction Y.

Referring to FIG. 4, the source region 23 has a first side portion 23A and a second side portion 23B that extend along the first direction X while being spaced apart from each other. The source region 23 has a third side portion 23C and a fourth side portion 23D (see FIG. 3) that connect the first side portion 23A and the second side portion 23B. The third side portion 23C and the fourth side portion 23D are formed in an arc shape that swells outward in the first direction X. The first side portion 23A to the fourth side portion 23D are all arranged inward from the peripheral edges (the first peripheral edge 61 to the fourth peripheral edge 64) of the back gate region 16 in a plan view. That is, the source region 23 is formed in the surface layer portion of the back gate region 16 to be spaced inward from the peripheral edges (the first peripheral edge 61 to the fourth peripheral edge 64) of the back gate region 16.

A third width W₃ of each source region 23 in the second direction Y is 0.8 μm or more and 1.0 μm or less. The third width W₃ may be constant over the entire region in the first direction X. Both end portions of the pair of source regions 23 may be aligned in the first direction X. Each source region 23 may be formed in a square shape that extends long in the first direction X in a plan view.

Referring to FIG. 4, the back gate contact region 24 is exposed from the field insulating film 19 at the third opening portion 43. The back gate contact region 24 has a band shape extending along the first direction X. The back gate contact region 24 is formed adjacent to the source region 23. The back gate contact region 24 is a p-type impurity region. The back gate contact region 24 may have a higher p-type impurity concentration than the back gate region 16. The p-type impurity concentration of the back gate contact region 24 may be, for example, 1.0×10¹⁹ cm⁻³ or more and 2.0×10²⁰ cm⁻³ or less.

Referring to FIG. 4, the back gate contact region 24 has a first side portion 24A and a second side portion 24B that extend along the first direction X while being spaced apart from each other. The back gate contact region 24 has a third side portion 24C and a fourth side portion 24D (see FIG. 3) that connect the first side portion 24A and the second side portion 24B. The third side portion 24C and the fourth side portion 24D are formed in an arc shape that swells outward in the first direction X. The first side portion 24A to the fourth side portion 24D are all arranged inward from the peripheral edges (the first peripheral edge 61 to the fourth peripheral edge 64) of the back gate region 16 in a plan view. That is, the back gate contact region 24 is formed in the surface layer portion of the back gate region 16 to be spaced inward from the peripheral edges (the peripheral edge 61 to the fourth peripheral edge 64) of the back gate region 16.

Referring to FIG. 7, a fourth width W₄ of the back gate contact region 24 in the second direction Y is 0.6 μm or more and 0.8 μm or less. The fourth width W₄ is smaller than the third width W₃ (W₄<W₃). The fourth width W₄ may be the same as or larger than the third width W₃ (W₄≥W₃). The fourth width W₄ may be constant over the entire region in the first direction X. The back gate contact region 24 may be formed in a square shape that extends long in the first direction X in a plan view.

Referring to FIGS. 4 and 7, the back gate contact region 24 and the source region 23 are electrically isolated by the field insulating film 19 in the surface layer portion of the back gate region 16. The back gate contact region 24 and the source region 23 are adjacent to each other while being spaced apart from each other in the second direction Y. Referring to FIG. 4, a first interval W₁₁ between the back gate contact region 24 and the source region 23 in the second direction Y is 0.8 μm or more and 1.0 μm or less. The first interval Wₙ is larger than the fourth width W₄ (W₁₁>W₄). The first interval W₁₁ may be the same as or smaller than the fourth width W₄ (W₁₁≤W₄).

Referring to FIGS. 2 and 7, the first impurity region 25 is a p-type impurity region. The first impurity region 25 is formed on the side of the second main surface 4 with respect to the back gate region 16. The first impurity region 25 overlaps the back gate region 16 in a plan view. As shown in FIG. 7, the first impurity region 25 may be in contact with the back gate region 16. Although not shown, the first impurity region 25 may be spaced apart from the back gate region 16 in a depth direction (so as to approach the second main surface 4).

The p-type impurity concentration of the first impurity region 25 may be, for example, 1.0×10¹⁵ cm⁻³ or more and 5.0×10¹⁶ cm⁻³ or less. The p-type impurity concentration of the first impurity region 25 may be the same as the p-type impurity concentration of the high concentration portion 35 of the back gate region 16. The p-type impurity concentration of the first impurity region 25 may be lower than the p-type impurity concentration of the high concentration portion 35. The p-type impurity concentration of the first impurity region 25 may be higher than the p-type impurity concentration of the high concentration portion 35.

Referring to FIGS. 2 and 7, the first impurity region 25 is formed in an elliptical shape that extends long in the first direction X in a plan view. The first impurity region 25 has a first peripheral edge 71 and a second peripheral edge 72 that extend linearly along the first direction X while being spaced apart from each other. The first impurity region 25 has a third peripheral edge 73 and a fourth peripheral edge 74 that connect the first peripheral edge 71 and the second peripheral edge 72. The third peripheral edge 73 and the fourth peripheral edge 74 face each other in the first direction X. The third peripheral edge 73 and the fourth peripheral edge 74 are formed in an arc shape that swells outward in the first direction X. The first peripheral edge 71, the second peripheral edge 72, the third peripheral edge 73, and the fourth peripheral edge 74 of the first impurity region 25 are spaced inward from the first peripheral edge 61, the second peripheral edge 62, the third peripheral edge 63, and the fourth peripheral edge 64 of the back gate region 16, respectively.

Referring to FIGS. 2 and 7, the first impurity region 25 is not formed in a region facing the gate electrode 20 in the depth direction (the third direction Z). That is, the first impurity region 25 is not formed in a region facing the channel region 53 in the depth direction (the third direction Z).

Referring to FIG. 7, a depth of a bottom of the first impurity region 25 is smaller than that of the bottom of the first well region 15. The first impurity region 25 is in contact with the high concentration portion 35 of the back gate region 16. The first impurity region 25 is not in contact with the low concentration portion 36 of the back gate region 16.

Referring to FIG. 7, the second impurity region 26 is a p-type region. The second impurity region 26 is formed on the side of the second main surface 4 with respect to the second well region 18. Although not shown, the second impurity region 26 overlaps the second well region 18 in a plan view. Although not shown, the second impurity region 26 has a square annular shape. The second impurity region 26 may be in contact with the second well region 18. Although not shown, the second impurity region 26 may be formed to be spaced apart from the second well region 18 in the depth direction (so as to approach the second main surface 4).

The p-type impurity concentration of the second impurity region 26 may be, for example, 1.0×10¹⁵ cm⁻³ or more and 5.0×10¹⁶ cm⁻³ or less. The p-type impurity concentration of the second impurity region 26 is the same as the p-type impurity concentration of the second well region 18. A depth of a bottom of the second impurity region 26 is the same as that of the bottom of the first impurity region 25. An inner peripheral end of the second impurity region 26 is spaced outward from an inner peripheral end of the second well region 18. An outer peripheral end of the second impurity region 26 is spaced inward from an outer peripheral end of the second well region 18.

Referring to FIG. 6, the second impurity region 26 is formed to surround sides of the first impurity region 25. In other words, the second impurity region 26 faces the first impurity region 25 while being spaced apart from each other in the first direction X and the second direction Y.

Referring to FIGS. 6 and 7, the interlayer insulating film 27 is formed over the first main surface 3 of the semiconductor chip 2. The interlayer insulating film 27 covers the gate electrode 20. The interlayer insulating film 27 is made of, for example, silicon oxide (SiO₂), silicon nitride (SiN₂), or the like. In the present embodiment, the interlayer insulating film 27 is formed of a single layer film of silicon oxide but may be formed of a plurality of interlayer insulating films 27.

Referring to FIG. 7, the drain wiring 28 is formed over the interlayer insulating film 27. The drain wiring 28 is electrically connected to the first drain region 21 and the second drain region 22 via the first drain contact 29 and the second drain contact 30, respectively. Referring to FIGS. 4 and 7, the first drain contact 29 is formed to penetrate the interlayer insulating film 27 at a position overlapping the first drain region 21 in a plan view. More specifically, the first drain contact 29 is electrically connected to the first drain region 21 via the silicide layer 60. The first drain contact 29 may include a plurality of first drain contacts 29 arranged along the first direction X. Although not shown, the first drain contact 29 may be one long first drain contact 29 along the first direction X.

Referring to FIGS. 4 and 7, the second drain contact 30 is formed to penetrate the interlayer insulating film 27 at a position overlapping the second drain region 22 in a plan view. More specifically, the second drain contact 30 is electrically connected to the second drain region 22 via the silicide layer 60. The second drain contact 30 may include a plurality of second drain contacts 30 arranged along the first direction X. Although not shown, the second drain contact 30 may be one long second drain contact 30 along the first direction X.

Referring to FIG. 7, the source wiring 31 is formed over the interlayer insulating film 27. The source wiring 31 is electrically connected to the source region 23 via the source contact 32. Referring to FIGS. 4 and 7, the source contact 32 is formed to penetrate the interlayer insulating film 27 at a position overlapping the source region 23 in a plan view. More specifically, the source contact 32 is electrically connected to the source region 23 via the silicide layer 60. The source contact 32 includes a plurality of source contacts 32 arranged along the first direction X.

Referring to FIG. 7, the back gate wiring 33 is formed over the interlayer insulating film 27. The back gate wiring 33 is electrically connected to the back gate contact region 24 via the back gate contact 34. Referring to FIGS. 4 and 7, the back gate contact 34 is formed to penetrate the interlayer insulating film 27 at a position overlapping the back gate contact region 24 in a plan view. More specifically, the back gate contact 34 is electrically connected to the back gate contact region 24 via the silicide layer 60. The back gate contact 34 may include a plurality of back gate contacts 34 arranged along the first direction X.

Referring to FIG. 4, a plurality of source contacts 32 connected to one source region 23 are aligned in the first direction X with a plurality of source contacts 32 connected to the other source region 23. The source contact 32 and the back gate contact 34 are electrically isolated. The source contact 32 and the back gate contact 34 may be aligned in the first direction X with the drain contacts (the first drain contact 29 and the second drain contact 30).

Although the drain wiring 28, the source wiring 31, and the back gate wiring 33 are made of aluminum (Al) in the present embodiment, they may be made of other conductive materials (for example, copper (Cu), etc.). The drain wiring 28, the source wiring 31, and the back gate wiring 33 may be referred to as a drain conductive layer, a source conductive layer, and a back gate conductive layer, respectively.

Although the first drain contact 29, the second drain contact 30, the source contact 32, and the back gate contact 34 are made of tungsten (W) in the present embodiment, they may be made of other conductive materials (for example, aluminum (Al), copper (Cu), etc.). In this case, it goes without saying that a barrier film such as TiN may be used.

Further, although not shown, a gate contact mechanically and electrically connected to the gate electrode 20 is buried in the interlayer insulating film 27. The gate contact is electrically isolated from the first drain contact 29, the second drain contact 30, the source contact 32, and the back gate contact 34.

As described above, in the LDMOSFET 10, the source region 23 and the back gate contact region 24 are formed to be electrically separated from each other. Therefore, a connection destination of the back gate contact region 24 can be switched between the source region 23 and the first drain region 21.

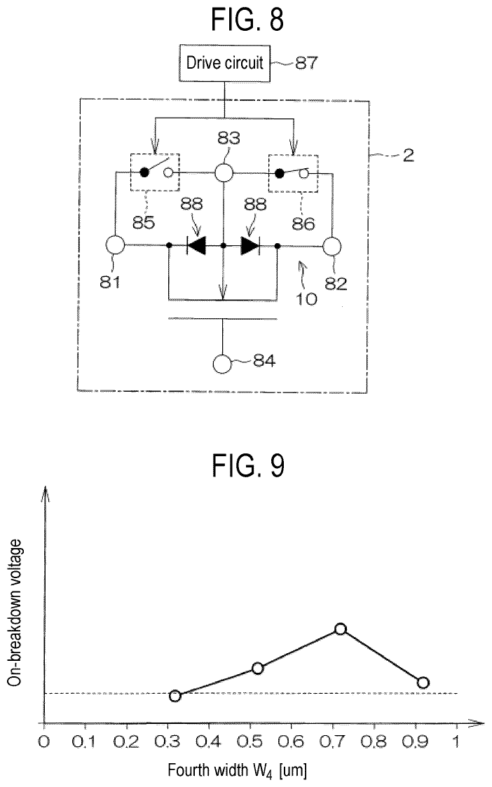

FIG. 8 is an electrical circuit diagram of the semiconductor chip 2. The semiconductor chip 2 includes an LDMOSFET 10 and two body diodes 88. The semiconductor chip 2 includes a source terminal electrode 81, a drain terminal electrode 82, a back gate terminal electrode 83, and a gate terminal electrode 84. The source terminal electrode 81, the drain terminal electrode 82, the back gate terminal electrode 83, and the gate terminal electrode 84 are formed at an outer surface of the semiconductor chip 2. The source wiring 31 (see FIG. 7) of the LDMOSFET 10 is electrically connected to the source terminal electrode 81. The source terminal electrode 81 may also be referred to as an output terminal. The drain wiring 28 (see FIG. 7) of the LDMOSFET 10 is electrically connected to the drain terminal electrode 82. The drain terminal electrode 82 may also be referred to as an input terminal. The back gate wiring 33 (see FIG. 7) of the LDMOSFET 10 is electrically connected to the back gate terminal electrode 83. A gate wiring (not shown) of the LDMOSFET 10 is electrically connected to the gate terminal electrode 84. The above-described gate contact is electrically connected to the gate wiring.

A first switch 85 is arranged between the source terminal electrode 81 and the back gate terminal electrode 83. A second switch 86 is arranged between the drain terminal electrode 82 and the back gate terminal electrode 83. Opening and closing of the first switch 85 and the second switch 86 are switched by a drive circuit 87. A connection destination of the back gate terminal electrode 83 is selectively switched between the source terminal electrode 81 and the drain terminal electrode 82 by the first switch 85 and the second switch 86. When the LDMOSFET 10 is in an on state, the first switch 85 is in an open state and the second switch 86 is in a closed state. That is, the connection destination of the back gate terminal electrode 83 is the drain terminal electrode 82. When the LDMOSFET 10 is in an off state, the first switch 85 is in a closed state and the second switch 86 is in an open state. That is, the connection destination of the back gate terminal electrode 83 is the source terminal electrode 81.

The two body diodes 88 are formed in a path connecting the source terminal electrode 81 and the drain terminal electrode 82. These two body diodes 88 realize an overcurrent prevention function and a reverse current prevention function. Regardless of whether the connection destination of the back gate terminal electrode 83 is the source terminal electrode 81 or the drain terminal electrode 82, a current flows through the two body diodes 88. That is, the semiconductor chip 2 can realize both the overcurrent prevention function and the reverse current prevention function in both the on state of the LDMOSFET 10 and the off state of the LDMOSFET 10.

In the present embodiment, one semiconductor chip 2 realizes both the overcurrent prevention function and the reverse current prevention function. Therefore, a size of a substrate on which the semiconductor chip 2 is arranged can be reduced as compared to a case where a total of two chips, one having an overcurrent prevention function and the other having a reverse current prevention function, are used.

Further, in a case where both an LDMOSFET for overcurrent prevention function and an LDMOSFET for reverse current prevention function are to be mounted on one chip, there is a risk that a chip size may increase.

In contrast, in the present embodiment, only one LDMOSFET 10 is formed on one semiconductor chip 2. Therefore, a chip size of the semiconductor chip 2 can be reduced as compared to a case where both an LDMOSFET for overcurrent prevention function and an LDMOSFET for reverse current prevention function are mounted on one chip.

In the semiconductor device disclosed in the related art, the source region and the back gate contact region are electrically connected to the same source wiring. That is, the semiconductor device in the related art employs a butting structure of a source and a back gate. In such a semiconductor device, a decrease in on-breakdown voltage is suppressed.

In contrast, in the present embodiment, the source region 23 and the back gate contact region 24 are formed to be electrically separated from each other in order to realize both the overcurrent prevention function and the reverse current prevention function in one semiconductor chip 2. That is, a structure in which the source and the back gate are separated from each other is adopted. Since the back gate and the source are separated from each other, there is a concern that the on-breakdown voltage of the semiconductor chip 2 (semiconductor device 1) will decrease.

FIG. 9 is a graph showing a relationship between the fourth width W₄ of the back gate contact region 24 in the second direction and the on-breakdown voltage of the semiconductor device 1. In FIG. 9, a lower limit of an allowable value of the on-breakdown voltage is shown by a broken line.

The on-breakdown voltage of the semiconductor device 1 depends on the fourth width W₄ of the back gate contact region 24. From FIG. 9, it can be seen that when the fourth width W₄ is 0.4 μm or more and 0.6 μm or less, the on-breakdown voltage of the semiconductor device 1 can be maintained high. As a result, even in a case where the semiconductor device 1 adopts the structure in which the source and the back gate are separated from each other, a decrease in the on-breakdown voltage can be suppressed.

Further, in the present embodiment, the p-type first impurity region 25 is formed below the back gate region 16. By forming a p-type impurity region having a relatively high concentration below the back gate region 16, a decrease in the on-breakdown voltage of the semiconductor device 1 can be suppressed. On the other hand, the concentration of the surface portion of the back gate region 16 remains unchanged. Therefore, while suppressing an influence on element characteristics of the semiconductor device 1, a decrease in the on-breakdown voltage of the semiconductor device 1 can be suppressed.

Further, as described above, the first impurity region 25 is not formed in a region facing the channel region 53 in the depth direction (the third direction Z). If the first impurity region 25 is also formed in a region facing the channel region 53 in the depth direction, there is a risk that a value of the threshold voltage (V_{TH}) will deteriorate due to this. Therefore, in the present embodiment, the first impurity region 25 is not formed in the region facing the channel region 53 in the depth direction.

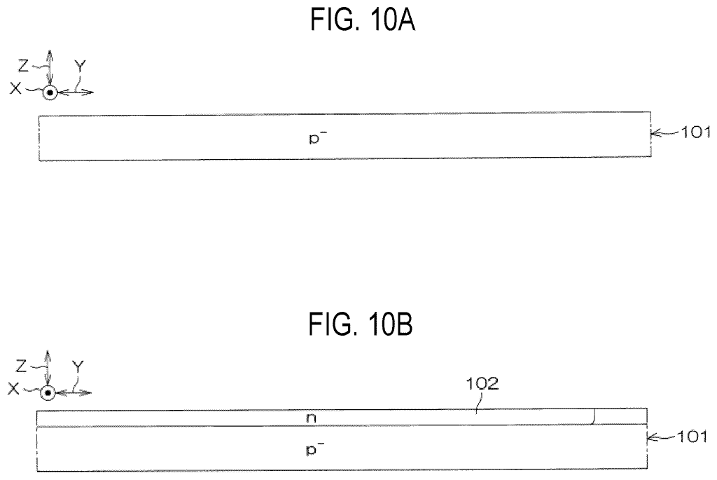

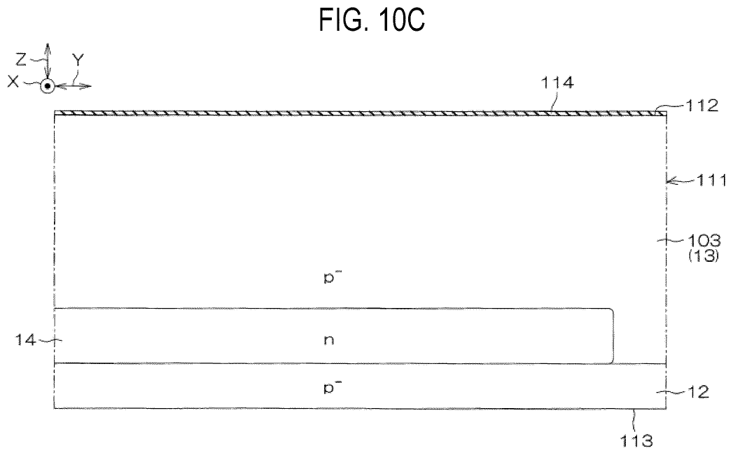

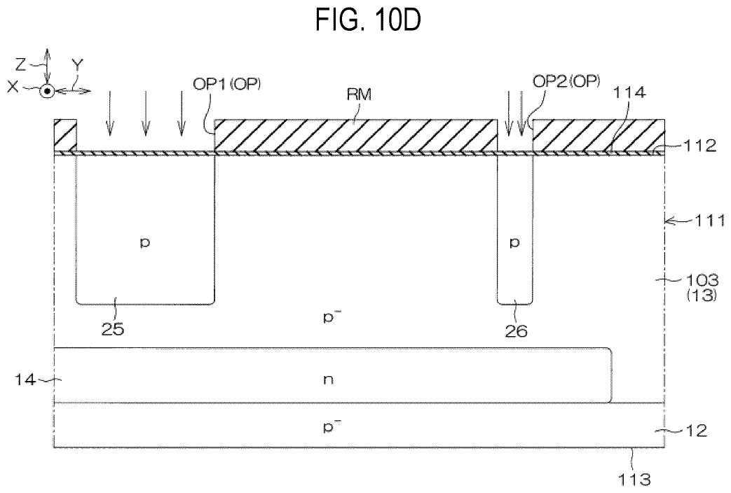

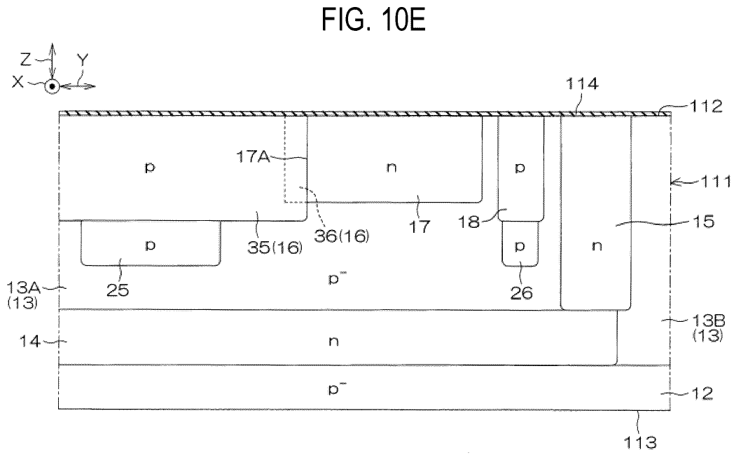

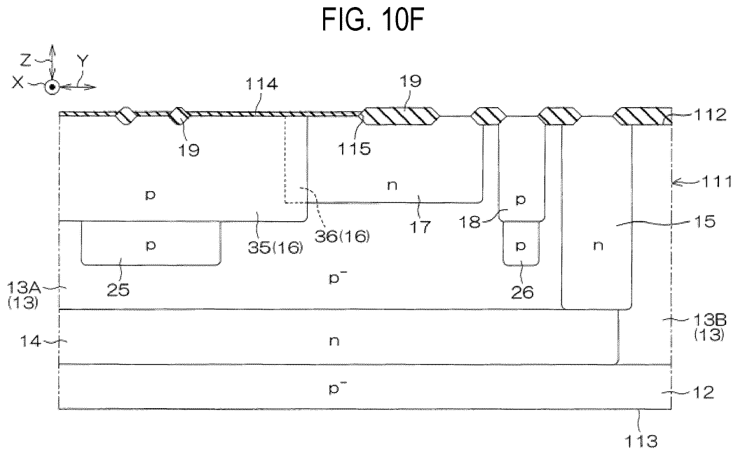

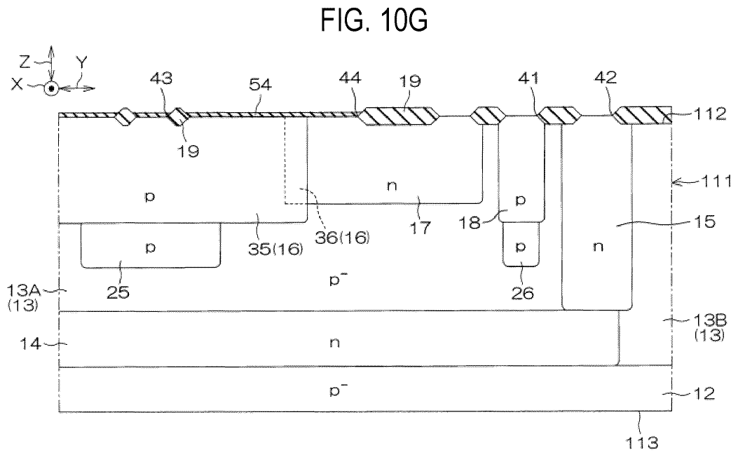

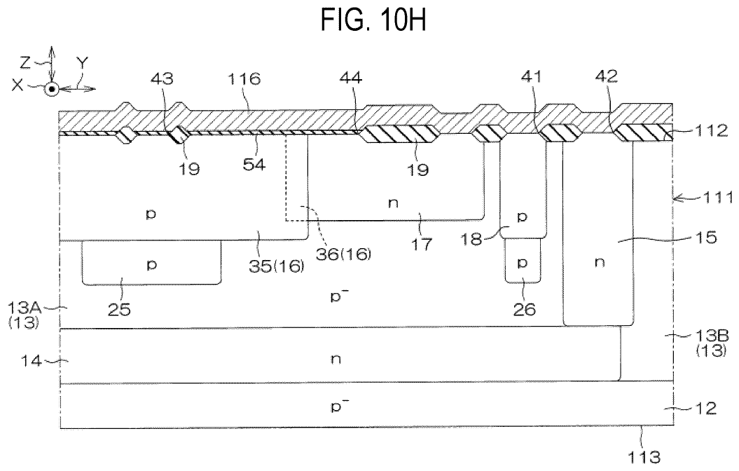

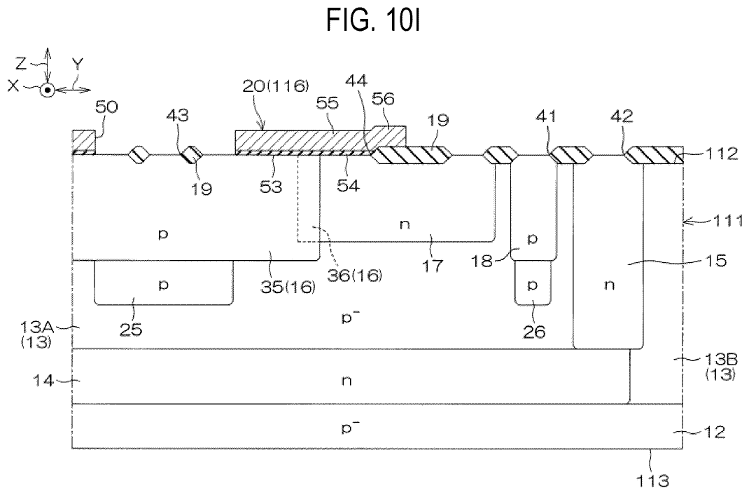

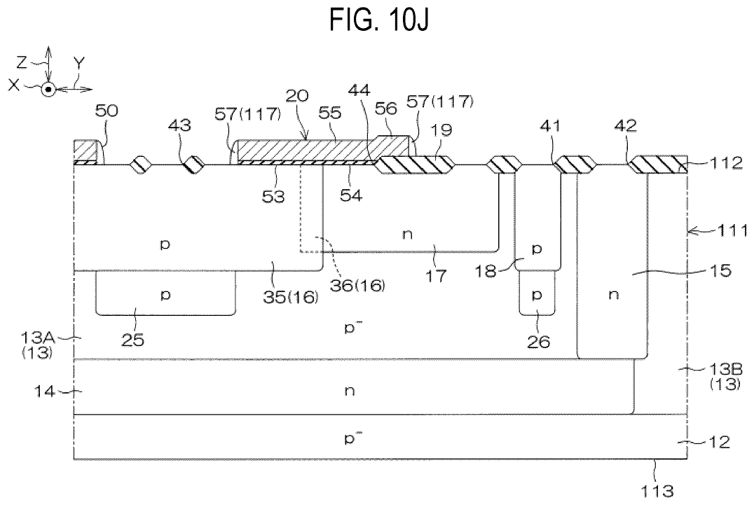

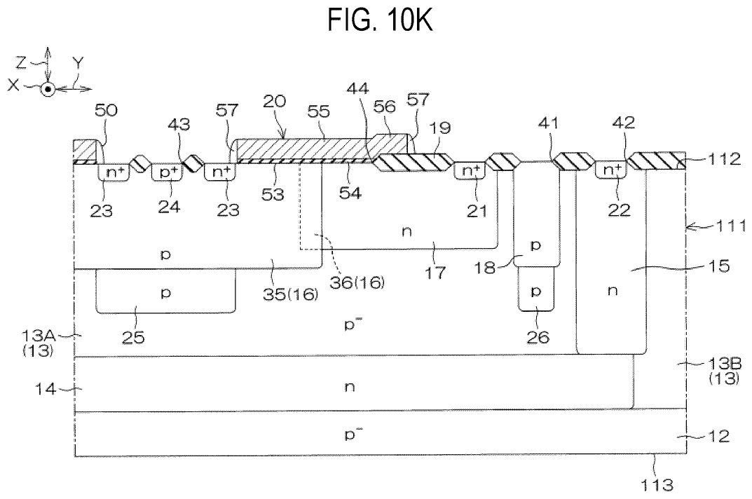

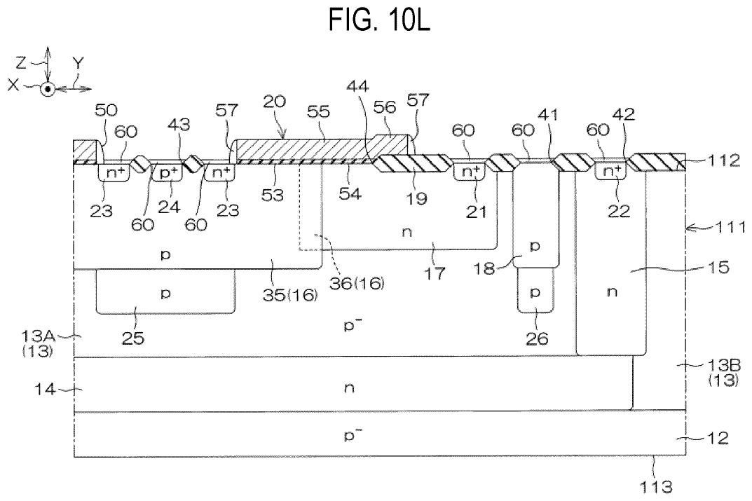

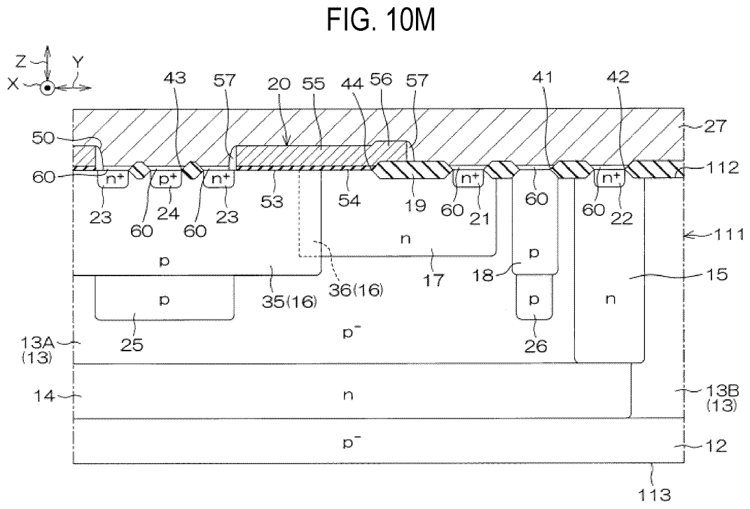

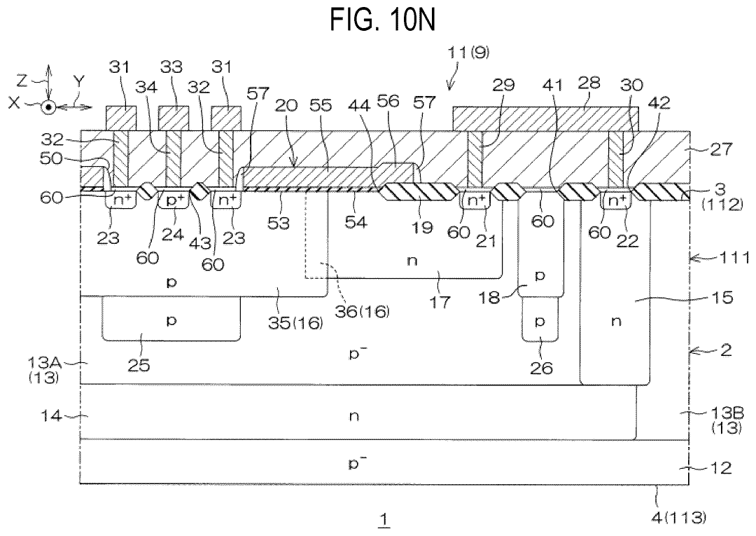

FIGS. 10A to 10N are views showing parts of a manufacturing process of the semiconductor device 1 in order of process. FIGS. 10A to 10N correspond to FIG. 7.

First, referring to FIG. 10A, a semiconductor wafer 101 is prepared. The semiconductor wafer 101 serves as a base of the semiconductor chip 2 (see FIGS. 6 and 7). The semiconductor wafer 101 is a p-type wafer. The semiconductor wafer 101 corresponds to the first p-type region 12 (see FIGS. 6 and 7) of the semiconductor device 1.

Next, referring to FIG. 10B, a hard mask (not shown) having an opening corresponding to a region where the buried region 14 (see FIGS. 6 and 7) is to be formed is arranged, and n-type impurities are selectively introduced into the surface portion of the semiconductor wafer 101 through the hard mask. As a result, an introduction portion 102 is formed on the surface portion of the semiconductor wafer 101. Examples of the n-type impurity may include P (phosphorus), As (arsenic), and the like.

Next, referring to FIG. 10C, an epitaxial layer 103 is formed by epitaxially growing silicon on the semiconductor wafer 101. By forming the epitaxial layer 103, a semiconductor wafer structure 111 including the second p-type region 13 is formed. The epitaxial layer 103 corresponds to the second p-type region 13. The n-type impurities of the introduction portion 102 introduced into the main surface of the semiconductor wafer 101 diffuse into the p-type epitaxial layer 103, thereby forming the buried region 14. The semiconductor wafer structure 111 has a first wafer main surface 112 on one side and a second wafer main surface 113 on the opposite side. The first wafer main surface 112 and the second wafer main surface 113 correspond to the first main surface 3 and the second main surface 4 (see FIGS. 6 and 7) of the semiconductor chip 2, respectively. Next, a sacrificial insulating film 114 is formed on the first wafer main surface 112. The sacrificial insulating film 114 may be, for example, a silicon oxide (SiO₂) film formed by thermally oxidizing a surface layer portion of the first wafer main surface 112 into a film shape.

Next, referring to FIG. 10D, the p-type first impurity region 25 and the p-type second impurity region 26 are formed.

Specifically, p-type impurities are selectively introduced into the first wafer main surface 112 via a resist mask RM. Examples of the p-type impurities (first impurity) may include B (boron), Al (aluminum), and the like. An opening OP of the resist mask RM corresponds to a region where the p-type first impurity region 25 and the p-type second impurity region 26 are to be formed. The opening OP of the resist mask RM includes an elliptical first opening OP1 (corresponding to the first impurity region 25) and an annular second opening OP2 (corresponding to the second impurity region 26) surrounding a side of the opening. After the introduction of the p-type impurities, the resist mask RM is removed from the semiconductor wafer structure 111. Next, the introduced p-type impurities are diffused by heat-treating the semiconductor wafer structure 111. As a result, the p-type first impurity region 25 and the p-type second impurity region 26 are formed.

As described above, a pattern of the opening OP of the resist mask RM has the elliptical first opening OP1 and the annular second opening OP2. If the pattern of the opening OP of the resist mask RM only has the first opening OP1, there is a risk that the peripheral edge of the first opening OP1 will be pulled by the surrounding resist and spread outward. Therefore, there is a risk that an outer peripheral edge of the first impurity region 25 formed by using the first opening OP1 may be displaced outward from its intended position. In this case, there is a risk that the outer peripheral edge of the first impurity region 25 is disposed in a region facing the channel region 53 in the depth direction (the third direction Z).

In contrast, in the present embodiment, since the second opening OP2 is formed in the resist mask RM, no outward-pulling force acts on the peripheral edge of the first opening OP1. Therefore, the peripheral edge of the first opening OP1 does not spread outward. As a result, the outer peripheral edge of the first impurity region 25 is not displaced from its intended position. Therefore, the outer peripheral edge of the first impurity region 25 can be reliably prevented from facing the channel region 53 in the depth direction (the third direction Z).

Next, referring to FIG. 10E, the first well region 15, the back gate region 16, the drift region 17, and the second well region 18 are formed in the surface layer portion of the first wafer main surface 112.

Specifically, the first well region 15 is formed by implanting n-type impurities into the surface layer portion of the first wafer main surface 112 by ion implantation through the sacrificial insulating film 114. The bottom of the first well region 15 reaches the buried region 14. By forming the annular first well region 15, the second p-type region 13 is partitioned into the p-type inner region 13A and the p-type outer region 13B. The p-type inner region 13A is surrounded by an n-type region including the buried region 14 and the first well region 15 in the first direction X, the second direction Y, and the third direction Z. As a result, the p-type inner region 13A is electrically isolated from the p-type outer region 13B and the first p-type region 12 by the n-type region including the buried region 14 and the first well region 15.

Further, the back gate region 16 and the second well region 18 are formed in the surface layer portion of the first wafer main surface 112. Specifically, p-type impurities are implanted into the surface layer portion of the first wafer main surface 112 by ion implantation through the sacrificial insulating film 114, thereby forming the back gate region 16 and the second well region 18.

Next, the drift region 17 is formed in the surface layer portion of the first wafer main surface 112. Specifically, the drift region 17 is formed by implanting n-type impurities into the surface layer portion of the first wafer main surface 112 by ion implantation through the sacrificial insulating film 114. The bottom of the drift region 17 does not reach the buried region 14.

In the ion implantation used to form the drift region 17, the n-type impurities are introduced up to a region inside the inner peripheral edge 17A of the drift region 17. As a result, the inner peripheral edge 17A of the drift region 17 can be reliably connected to the back gate region 16. By introducing the n-type impurities up to the region inside the inner peripheral edge 17A of the drift region 17, the p-type impurities of the peripheral edge of the back gate region 16 are reduced. As a result, the low concentration portion 36 is formed at the peripheral edge of the back gate region 16. Since a dose of p-type impurities is smaller than a dose of n-type impurities, the peripheral edge of the back gate region 16 is maintained as a p-type impurity region.

An order of forming the first well region 15, the back gate region 16, the drift region 17, and the second well region 18 can be changed as appropriate. For example, the back gate region 16 may be formed first, and then the drift region 17 may be formed. Alternatively, for example, the drift region 17 may be formed first, and then the first well region 15 may be formed.

Next, referring to FIG. 10F, a hard mask (not shown) is formed over the sacrificial insulating film 114, and the sacrificial insulating film 114 is selectively removed by etching through the hard mask, thereby forming an opening 115. Next, the field insulating film 19 is formed by thermally oxidizing the surface layer portion of the first wafer main surface 112 exposed through the opening 115 of the sacrificial insulating film 114. After that, the sacrificial insulating film 114 is removed.

Next, referring to FIG. 10G, the gate insulating film 54 is formed over the first wafer main surface 112. For example, the gate insulating film 54 may also be a silicon oxide (SiO₂) film formed by thermally oxidizing the surface layer portion of the first wafer main surface 112, which is exposed through the first opening portion 41, the second opening portion 42, the third opening portion 43, and the fourth opening portion 44 of the field insulating film 19, into a film shape.

Next, referring to FIG. 10H, a base electrode 116 serving as a base of the gate electrode 20 (see FIGS. 6 and 7) is formed over the first wafer main surface 112 so as to cover the gate insulating film 54 and the field insulating film 19. In present embodiment, the base electrode 116 is made of conductive polysilicon. The base electrode 116 may be formed by, for example, a CVD method.

Next, referring to FIG. 10I, unnecessary portions of the base electrode 116 are removed by etching through a hard mask (not shown) having a predetermined pattern. As a result, the gate electrode 20 is formed. The etching may be, for example, dry etching (for example, an RIE method) or wet etching. Thereafter, the gate insulating film 54 exposed from the gate electrode 20 is removed, such that the back gate region 16 is exposed from the opening portion 50 and the first well region 15 is exposed from the first opening portion 41 of the field insulating film 19.

Next, referring to FIG. 10J, a base insulating film 117 serving as a base of the sidewall structure 57 is sequentially formed over the first wafer main surface 112. The base insulating film 117 may be formed by, for example, a CVD method. Next, unnecessary portions of the base insulating film 117 are removed by etch-back. As a result, the sidewall structure 57 is formed by the base insulating film 117 remaining on the inner and outer side portions of the gate electrode 20.

Next, referring to FIG. 10K, the first drain region 21 and the second drain region 22 are formed in the surface layer portions of the drift region 17 and the first well region 15, respectively. Further, the source region 23, the back gate contact region 24, the first drain region 21, and the second drain region 22 are formed in the surface layer portion of the back gate region 16. In the present embodiment, the source region 23 and the back gate contact region 24 are formed by implanting n-type impurities and p-type impurities into the surface layer portion of the back gate region 16 by ion implantation using the sidewall structure 57 and the field insulating film 19 as hard masks. That is, the source region 23 and the back gate contact region 24 are formed in self-alignment with the peripheral edge of the sidewall structure 57 of the gate electrode 20 and the peripheral edge of the third opening portion 43, respectively. The first drain region 21 is formed by implanting n-type impurities into the surface layer portion of the drift region 17 by ion implantation using the field insulating film 19 as a hard mask. That is, the first drain region 21 is formed in self-alignment with the peripheral edge of the first opening portion 41 of the field insulating film 19. The second drain region 22 is formed by implanting n-type impurities into the surface layer portion of the first well region 15 by ion implantation using the field insulating film 19 as a hard mask. That is, the second drain region 22 is formed in self-alignment with the peripheral edge of the second opening portion 42 of the field insulating film 19.

Next, referring to FIG. 10L, the silicide layer 60 is formed. To form the silicide layer 60, first, the above-mentioned transition metal is deposited over the second p-type region 13 and the gate electrode 20 and then is heat treated. An exposed portion (silicon) of each of the second p-type region 13 and the gate electrode 20 and the transition metal react to form the silicide layer 60.

Next, referring to FIG. 10M, the interlayer insulating film 27 is formed over the first wafer main surface 112. The interlayer insulating film 27 may be formed by, for example, a CVD method.

Next, referring to FIG. 10N, the first drain contact 29, the second drain contact 30, the source contact 32, and the back gate contact 34 are formed in the interlayer insulating film 27 by etching through a hard mask (not shown) having a predetermined pattern, forming a metal film by a CVD method, and etching an unnecessary metal film. Next, a base wiring film serving as a base for a plurality of wirings is formed over the interlayer insulating film 27 and is patterned to form the drain wiring 28, the source wiring 31, and the back gate wiring 33. Thereafter, the semiconductor wafer structure 111 is cut, and a plurality of semiconductor chips 2 are cut out. The semiconductor device 1 is manufactured through the above-described steps.

Although the embodiment of the present disclosure has been described, the present disclosure may be implemented in other forms.

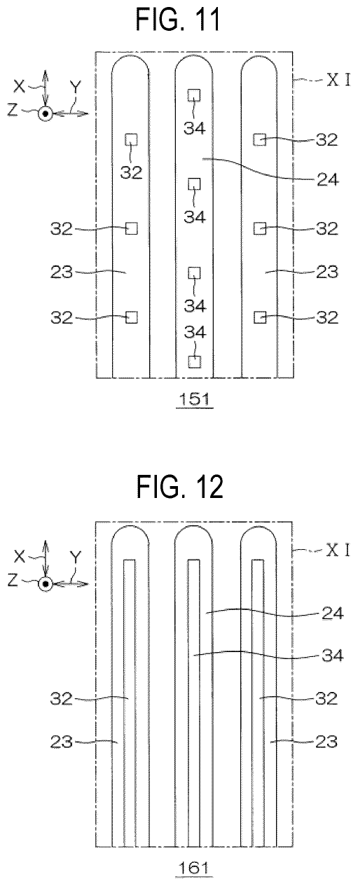

As in a semiconductor device 151 shown in FIG. 11, the back gate contact 34 and the source contact 32 may be arranged so as to be shifted from each other in the first direction X in a plan view. Even in this case, a plurality of back gate contacts 34 connected to one source region 23 may be aligned with the plurality of back gate contacts 34 connected to the other source region 23 in the first direction X.

Further, as in a semiconductor device 161 shown in FIG. 12, the back gate contact 34 may have a line shape extending along the first direction X, instead of a dot shape (square shape). Further, as shown in FIG. 12, the source contact 32 may have a line shape extending along the first direction X, instead of a dot shape (square shape).

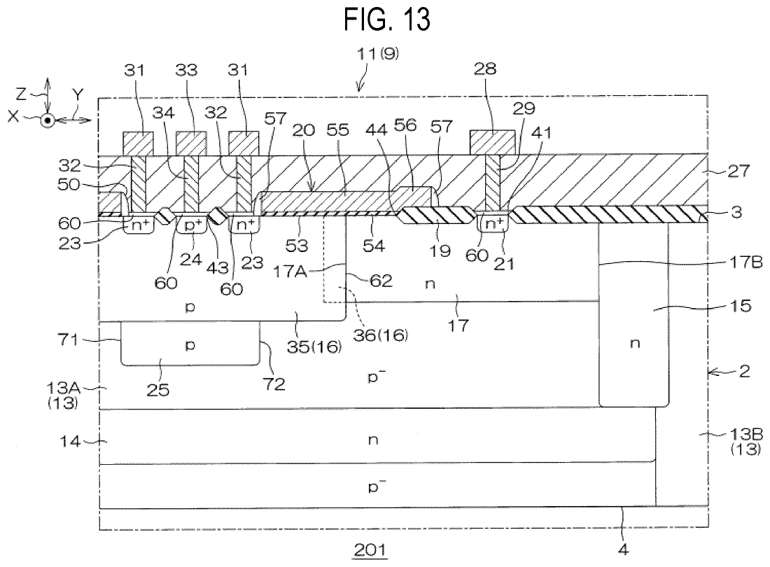

FIG. 13 is a schematic cross-sectional view of a semiconductor device 201 according to another embodiment of the present disclosure, which corresponds to FIG. 7. In FIG. 13, the same components as those described above are denoted by the same reference numerals, and explanation thereof will be omitted.

The semiconductor device 201 is different from the semiconductor device 1 according to the embodiment shown in FIGS. 1 to 10N in that the second well region 18 and the second impurity region 26 are eliminated. An outer peripheral edge 17B of the drift region 17 is in contact with the first well region 15 over the entire circumferential region of the drift region 17. Since the first well region 15 is in electrical contact with the drift region 17, the first well region 15 has the same potential as the drift region 17. Therefore, in the semiconductor device 201, a drain contact region (corresponding to the second drain contact 30 in the embodiment shown in FIGS. 1 to 10N) is not formed in the first well region 15.

According to the semiconductor device 201 according to another embodiment of the present disclosure, the same operation and effects as those described in connection with the embodiment shown in FIGS. 1 to 10N are achieved.

In each of the above-described embodiments, an example has been described in which the first conductivity type is an n type and the second conductivity type is a p type, but the first conductivity type may be a p type and the second conductivity type may be an n type. The specific configuration in this case can be obtained by replacing an n-type region with a p-type region and replacing a p-type region with an n-type region in the above description and the accompanying drawings.

As described above, the embodiments of the present disclosure are illustrative in all respects and should not be construed as limiting, and are intended to include changes in all respects.

The features described below can be extracted from the description of the present disclosure and the drawings. Hereinafter, alphanumeric characters in parentheses represent corresponding components in the above-described embodiments, but they are not intended to limit the scope of each clause to the embodiments.

### [Supplementary Note 1-1]

A semiconductor device (1, 151, 161, 201) including:
a semiconductor chip (2) having a first main surface (3) and a second main surface (4) opposite to the first main surface (3);
a first drain region (21) of a first conductivity type formed in a surface layer portion of the first main surface (3);
a back gate region (16) of a second conductivity type formed to be spaced apart from the first drain region (21) in the surface layer portion of the first main surface (3);
a source region (23) of the first conductivity type formed to be spaced inward from a peripheral edge (61 to 64) of the back gate region (16) in a surface layer portion of the back gate region (16);
a back gate contact region (24) of the second conductivity type formed to be electrically isolated from the source region (23) in the surface layer portion of the back gate region (16); and
a gate electrode (20) facing a channel region (53) formed in the back gate region (16) between the peripheral edge (61 to 64) of the back gate region (16) and the source region (23).

According to the above-described configuration, the source region (23) and the back gate contact region (24) are formed to be electrically isolated from each other. Therefore, the connection destination of the back gate contact region (24) can be switched between the source region (23) and the first drain region (21).

### [Supplementary Note 1-2]

The semiconductor device (1, 151, 161, 201) of Supplementary Note 1-1, wherein the back gate region (16) has a band shape extending in a first direction (X) along the first main surface (3), and
wherein the source region (23) and the back gate contact region (24) are formed while being spaced apart from each other in a second direction (Y) intersecting the first direction (X).

### [Supplementary Note 1-3]

The semiconductor device (1, 151, 161, 201) of Supplementary Note 1-2, wherein the source region (23) and the back gate contact region (24) have a band shape extending along the first direction (X).

### [Supplementary Note 1-4]

The semiconductor device (1, 151, 161, 201) of Supplementary Note 1-3, wherein a width (W₄) of the back gate contact region (24) in the second direction (Y) is 0.6 μm or more and 0.8 μm or less.

### [Supplementary Note 1-5]

The semiconductor device (1, 151, 161, 201) of Supplementary Note 1-3 or 1-4, wherein the source region (23) includes a pair of source regions (23) formed to sandwich the back gate contact region (24) in the second direction (Y).

### [Supplementary Note 1-6]

The semiconductor device (1, 151, 161, 201) of any one of Supplementary Notes 1-1 to 1-5, wherein the source region (23) and the back gate contact region (24) are electrically isolated from each other by a field insulating film (19) in the surface layer portion of the back gate region (16).

### [Supplementary Note 1-7]

The semiconductor device (1, 151, 161, 201) of any one of Supplementary Notes 1-1 to 1-6, further including:
an interlayer insulating film (27) covering the first main surface (3);
a back gate wiring (33) formed over the interlayer insulating film (27);
a source wiring (31) which is a wiring different from the back gate wiring (33) and is formed over the interlayer insulating film (27);
a back gate contact (34) which penetrates the interlayer insulating film (27) and connects the back gate region (16) and the back gate wiring (33); and
a source contact (32) which penetrates the interlayer insulating film (27) and connects the source region (23) and the source wiring (31).

### [Supplementary Note 1-8]

The semiconductor device (1, 151, 161, 201) of any one of Supplementary Notes 1-1 to 1-7, further including a first impurity region (25) of the second conductivity type formed below the back gate region (16).

### [Supplementary Note 1-9]

The semiconductor device (1, 151, 161, 201) of Supplementary Note 1-8, wherein the first impurity region (25) is formed so as not to face the channel region (53) in a depth direction (Z).

### [Supplementary Note 1-10]

The semiconductor device (1, 151, 161, 201) of Supplementary Note 1-8 or 1-9, wherein a peripheral edge (71 to 74) of the first impurity region (25) is formed to be spaced inward from the peripheral edge (61 to 64) of the back gate region (16) in a direction along the first main surface (3).

### [Supplementary Note 1-11]

The semiconductor device (1, 151, 161, 201) of any one of Supplementary Notes 1-8 to 1-10, wherein the first impurity region (25) is in contact with the back gate region (16).

### [Supplementary Note 1-12]

The semiconductor device (1, 151, 161) of any one of Supplementary Notes 1-8 to 1-11, further including a second impurity region (26) of the second conductivity type formed to surround a side of the first impurity region (25).

### [Supplementary Note 1-13]

The semiconductor device (1, 151, 161, 201) of any one of Supplementary Notes 1-1 to 1-12, further including a drift region (17) of the first conductivity type formed in the surface layer portion of the first main surface (3), wherein the first drain region (21) is formed in a surface layer portion of the drift region (17).

### [Supplementary Note 1-14]

The semiconductor device (1, 151, 161, 201) of Supplementary Note 1-13, wherein the back gate region (16) includes a first portion (35) in which the source region (23) and the back gate contact region (24) are formed, and a second portion (36) which is formed to be closer to the drift region (17) than the first portion and has a lower second conductivity type impurity concentration than the first portion (35).

### [Supplementary Note 1-15]

The semiconductor device (1, 151, 161, 201) of Supplementary Note 1-13 or 1-14, further including:
a well region (15) of the first conductivity type which has an annular shape in a plan view and is a region surrounding a side of a first region (13A) in which the back gate region (16) and the drift region (17) are formed in the surface layer portion of the first main surface (3); and
a buried region (14) covering a lower side of an entirety of the first region (13A),
wherein the well region (15) and the buried region (14) electrically isolate the first region (13A) from a second region (12, 13A) which is another region in the surface layer portion of the first main surface (3).

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device comprising:
a semiconductor chip having a first main surface and a second main surface opposite to the first main surface;
a first drain region of a first conductivity type formed in a surface layer portion of the first main surface;
a back gate region of a second conductivity type formed to be spaced apart from the first drain region in the surface layer portion of the first main surface;
a source region of the first conductivity type formed to be spaced inward from a peripheral edge of the back gate region in a surface layer portion of the back gate region;
a back gate contact region of the second conductivity type formed to be electrically isolated from the source region in the surface layer portion of the back gate region; and
a gate electrode facing a channel region formed in the back gate region between the peripheral edge of the back gate region and the source region.

2. The semiconductor device of claim 1, wherein the back gate region has a band shape extending in a first direction along the first main surface, and
wherein the source region and the back gate contact region are formed while being spaced apart from each other in a second direction intersecting the first direction.

3. The semiconductor device of claim 2, wherein the source region and the back gate contact region have a band shape extending along the first direction.

4. The semiconductor device of claim 3, wherein a width of the back gate contact region in the second direction is 0.6 μm or more and 0.8 μm or less.

5. The semiconductor device of claim 3, wherein the source region includes a pair of source regions formed to sandwich the back gate contact region in the second direction.

6. The semiconductor device of claim 1, wherein the source region and the back gate contact region are electrically isolated from each other by a field insulating film in the surface layer portion of the back gate region.

7. The semiconductor device of claim 1, further comprising:
an interlayer insulating film covering the first main surface;
a back gate wiring formed over the interlayer insulating film;
a source wiring which is a wiring different from the back gate wiring and is formed over the interlayer insulating film;
a back gate contact which penetrates the interlayer insulating film and connects the back gate region and the back gate wiring; and
a source contact which penetrates the interlayer insulating film and connects the source region and the source wiring.

8. The semiconductor device of claim 1, further comprising a first impurity region of the second conductivity type formed below the back gate region.

9. The semiconductor device of claim 8, wherein the first impurity region is formed so as not to face the channel region in a depth direction.

10. The semiconductor device of claim 8, wherein a peripheral edge of the first impurity region is formed to be spaced inward from the peripheral edge of the back gate region in a direction along the first main surface.

11. The semiconductor device of claim 8, wherein the first impurity region is in contact with the back gate region.

12. The semiconductor device of claim 8, further comprising a second impurity region of the second conductivity type formed to surround a side of the first impurity region.

13. The semiconductor device of claim 1, further comprising a drift region of the first conductivity type formed in the surface layer portion of the first main surface,
wherein the first drain region is formed in a surface layer portion of the drift region.

14. The semiconductor device of claim 13, wherein the back gate region includes a first portion in which the source region and the back gate contact region are formed, and a second portion which is formed to be closer to the drift region than the first portion and has a lower second conductivity type impurity concentration than the first portion.

15. The semiconductor device of claim 13, further comprising:
a well region of the first conductivity type which has an annular shape in a plan view and is a region surrounding a side of a first region in which the back gate region and the drift region are formed in the surface layer portion of the first main surface; and
a buried region covering a lower side of an entirety of the first region,
wherein the well region and the buried region electrically isolate the first region from a second region which is another region in the surface layer portion of the first main surface.
